(19) United States
(12) Patent Application Publication
(10) Pub. No.: US 2025/0096201 A1
(43) Pub. Date: Mar. 20, 2025

(54) SEMICONDUCTOR PACKAGE

(71) Applicant: Samsung Electronics Co., Ltd., Suwon-si (KR)

(72) Inventors: Gyujin CHOI, Suwon-si (KR); Dahee KIM, Suwon-si (KR); Hwan Pil PARK, Suwon-si (KR); Taehoon LEE, Suwon-si (KR); Younjeong CHOE, Suwon-si (KR)

(73) Assignee: Samsung Electronics Co., Ltd., Suwon-si (KR)

(21) Appl. No.: 18/599,390

(22) Filed: Mar. 8, 2024

(30) Foreign Application Priority Data
Sep. 14, 2023 (KR) 10-2023-0122465

(51) Int. Cl. H01L 25/065; H01L 21/56; H01L 23/00; H01L 23/31; H01L 25/16

(52) U.S. Cl. CPC H01L 25/0657; H01L 21/568; H01L 24/05; H01L 24/06; H01L 24/16; H01L 24/17; H01L 24/20; H01L 24/32; H01L 24/33; H01L 25/16; H01L 23/3128; H01L 24/19; H01L 24/95; H01L 2224/0557; H01L 2224/05624; H01L 2224/05647; H01L 2224/0603; H01L 2224/06181; H01L 2224/16145; H01L 2224/16225; H01L 2224/17181; H01L 2224/19; H01L 2224/211; H01L 2224/32145; H01L 2224/33181; H01L 2224/95; H01L 2225/06513; H01L 2225/06541; H01L 2225/06562

(57) ABSTRACT

The present disclosure relates to a semiconductor package which includes a wiring structure including insulating layers, wiring layers, and vias, a chip stack structure including a plurality of semiconductor chips and being oblique on the wiring structure such that the plurality of semiconductor chips are inclined with respect to the wiring structure, and a sealing material encapsulating the chip stack structure, wherein each of the plurality of semiconductor chips includes connection pads on one surface of the semiconductor chip, and the plurality of semiconductor chips are being offset with each other such that the connection pads are exposed, and each of the connection pads of each of the plurality of semiconductor chips is in contact with one of the vias and connected to the wiring layers.

### CROSS-REFERENCE TO RELATED APPLICATION

This application claims priority to and the benefit of Korean Patent Application No. 10-2023-0122465 filed in the Korean Intellectual Property Office on Sep. 14, 2023, the entire contents of which are incorporated herein by reference.

### BACKGROUND

### (a) Field

The present disclosure relates to semiconductor packages.

### (b) Description of the Related Art

With the development of electronic devices, multi-chip package technologies for mounting multiple semiconductor chips in one package are widely used to implement highly integrated packages with high capacity. Such multi-chip packages are implemented by processing a wafer thinly and stacking individual semiconductor chips. In order to connect the plurality of stacked semiconductor chips together, wire bonding techniques of attaching wire formed of a material with high electronic conductivity such as gold (Au) to the semiconductor chips are used.

The wire bonding techniques suffer from power loss and a decrease in transfer speed due to high impedance, and thus require a process of plating the coupling surfaces of wires with gold to ensure the reliability of the contact surfaces of the wires. Further, to maintain package thickness, as the number of semiconductor chips to be stacked increases, each semiconductor chip should be processed thinly, which increases handling difficulty.

For this reason, a novel semiconductor package structure capable of replacing the wire bonding techniques in highly integrated packages is required.

### SUMMARY

The present disclosure provides semiconductor packages with improved power and signal characteristics.

Also, the present disclosure provides semiconductor packages capable of mitigating or preventing an increase in package thickness and process difficulty due to the number of semiconductor chips that are stacked.

Further, the present disclosure implements fine circuits and provide semiconductor packages with an increased number of channels for increased bandwidth.

Furthermore, the present disclosure provides semiconductor package implemented as a system-in-package (SIP).

According to an example embodiment of the present disclosure, a semiconductor package includes a wiring structure including insulating layers, wiring layers, and vias, a chip stack structure including a plurality of semiconductor chips, the chip stack structure being oblique on the wiring structure such that the plurality of semiconductor chips is inclined with respect to the wiring structure, and a sealing material encapsulating the chip stack structure, wherein each of the plurality of semiconductor chips includes connection pads on one surface thereof, the plurality of semiconductor chips being offset with each other such that the connection pads are exposed, and each of the connection pads of each of the plurality of semiconductor chips is in contact with a corresponding one of the vias and connected to the wiring layers.

According to an example embodiment of the present disclosure, a semiconductor package includes a wiring structure, a first chip stack structure on the wiring structure and including a plurality of first semiconductor chips, the plurality of first semiconductor chips being offset with each other, the first chip stack structure being oblique along a first direction such that the plurality of first semiconductor chips are inclined with respect to the wiring structure, a first sealing material encapsulating the first chip stack structure, a second chip stack structure on the first chip stack structure and including a plurality of second semiconductor chips being offset with each other, and the second chip stack structure being oblique along a second direction forming an angle with the first direction, and a second sealing material encapsulating the second chip stack structure, wherein each of the plurality of first semiconductor chips includes first connection pads being on one end portion thereof and electrically connected to the wiring structure and second connection pads on another end portion thereof, the one end portion and the another end portion of each of the plurality of first semiconductor chips being opposite to each other, and each of the plurality of second semiconductor chips includes third connection pads being on one end portion thereof and electrically connected to the second connection pad.

According to an example embodiment of the present disclosure, a semiconductor package includes a first semiconductor package and a second semiconductor package on the first semiconductor package, wherein the first semiconductor package includes a wiring structure, a chip stack structure including a plurality of first semiconductor chips being offset with each other, the chip stack structure being oblique on the wiring structure such that the plurality of first semiconductor chips are inclined with respect to the wiring structure, and a sealing material encapsulating the chip stack structure, wherein each of the plurality of first semiconductor chips includes first connection pads being on one end portion thereof and electrically connected to the wiring structure and second connection pads being on another end portion of first semiconductor chip and electrically connected to the second semiconductor package, and wherein the second semiconductor package includes a plurality of second semiconductor chips.

According to an aspect, the present disclosure may provide a semiconductor package with improved power and signal characteristics.

According to another aspect, the present disclosure may provide a semiconductor package capable of mitigating or preventing an increase in package thickness and process difficulty due to the number of semiconductor chips that are stacked.

According to another aspect, the present disclosure may implement fine circuits and provide a semiconductor package with an increased number of channels for increased bandwidth.

According to another aspect, the present disclosure may provide a semiconductor package implemented as a system-in-package (SIP).

### BRIEF DESCRIPTION OF THE DRAWINGS

FIG. 1 is a cross-sectional view of a semiconductor package according to an example embodiment of the present disclosure.

FIG. 2 is a cross-sectional view of a semiconductor package according to an example embodiment of the present disclosure.

FIG. 3 is a cross-sectional view of a semiconductor package according to an example embodiment of the present disclosure.

FIG. 4 is a cross-sectional view of a semiconductor package according to an example embodiment of the present disclosure.

FIG. 5 is a cross-sectional view of a chip stack structure according to an example embodiment of the present disclosure.

FIG. 6 is a perspective view of the chip stack structure according to an example embodiment of the present disclosure.

FIG. 7 is a cross-sectional view of a chip stack structure according to an example embodiment of the present disclosure.

FIG. 8 is a cross-sectional view of a chip stack structure according to an example embodiment of the present disclosure.

FIG. 9 is a cross-sectional view of a chip stack structure according to an example embodiment of the present disclosure.

FIG. 10 is a cross-sectional view of a chip stack structure according to an example embodiment of the present disclosure.

FIG. 11 is a cross-sectional view of a chip stack structure according to an example embodiment of the present disclosure.

FIG. 12 is a cross-sectional view of a chip stack structure according to an example embodiment of the present disclosure.

FIG. 13 is a cross-sectional view of a semiconductor package according to an example embodiment of the present disclosure.

FIG. 14 is a cross-sectional view of a semiconductor package according to an example embodiment of the present disclosure.

FIG. 15 is a cross-sectional view of a semiconductor package according to an example embodiment of the present disclosure.

FIG. 16 is a cross-sectional view of a semiconductor package according to an example embodiment of the present disclosure.

FIGS. 17 to 19 illustrate a process of manufacturing the semiconductor package shown in FIG. 1, according to an example embodiment.

FIGS. 20 to 22 illustrate a process of manufacturing the semiconductor package shown in FIG. 2, according to an example embodiment.

### DETAILED DESCRIPTION

In the following detailed description, only certain example embodiments of the present disclosure have been shown and described, simply by way of illustration. The present disclosure can be variously implemented and is not limited to the following example embodiments.

The drawings and description are to be regarded as illustrative in nature and not restrictive. Like reference numerals designate like elements throughout the specification.

In addition, the size and thickness of each configuration shown in the drawings are arbitrarily shown for understanding and ease of description, but the present disclosure is not limited thereto. In the drawings, the thickness of layers, films, panels, regions, etc., are exaggerated for clarity. Further, in the drawings, for understanding and ease of description, the thickness of some layers and areas is exaggerated.

Throughout this specification, when a part is referred to as being “connected” to another part, it may be directly connected to the other part, or may be connected to the other part indirectly with any other elements interposed therebetween. From a similar point of view, when a part is referred to as being “connected” to another part, it may be physically connected to the other part, or may be electrically connected to the other part. In addition, unless explicitly described to the contrary, the word “comprise”, and variations such as “comprises” or “comprising”, will be understood to imply the inclusion of stated elements but not the exclusion of any other elements.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, in the entire specification, when it is referred to as “on a plane”, it means when a target part is viewed from above, and when it is referred to as “on a cross-section”, it means when the cross-section obtained by cutting a target part vertically is viewed from the side.

Furthermore, throughout this specification, the ordinal numbers such as first, second, or the like are used to distinguish an element from other elements identical or similar to the corresponding element, and are not necessarily intended to indicate a particular element. Accordingly, an element termed as a first element in a part of this specification may be termed as a second element in other parts of this specification.

Further, throughout this specification, elements expressed in the singular forms are intended to include the plural forms as well unless the context clearly indicates otherwise. For example, an insulating layer may be used to refer to not only one insulating layer but also a plurality of insulating layers, such as two, three, or more.

Furthermore, throughout this specification, one surface and the other surface are intended to distinguish between different surfaces, and are not intended to be limited to specific surfaces. Accordingly, a surface referred to as one surface in a part of this specification may also be referred to as the other surface in other parts of this specification.

Similarly, throughout this specification, one end portion and the other end portion are intended to distinguish between different end portions, and are not intended to be limited to specific end portions. Accordingly, a portion referred to as one end portion in a part of this specification may also be referred to as the other end portion in other parts of this specification.

Hereinafter, semiconductor packages according to some example embodiments of the present disclosure will be described with reference to the drawings.

Throughout this specification, the expressions “upper surface”, “upper side”, “lower surface”, and “lower side” are used to refer to the upper surface, the upper side, the lower surface, and the lower side as seen in the direction from a wiring structure 110 toward a chip stack structure 120 in the drawings. Throughout this specification, the upper surface, the upper side, the lower surface, and the lower side may be referred to as one surface or the other surface, one side or the other side, the other surface or one surface, and the other side or one side, respectively.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

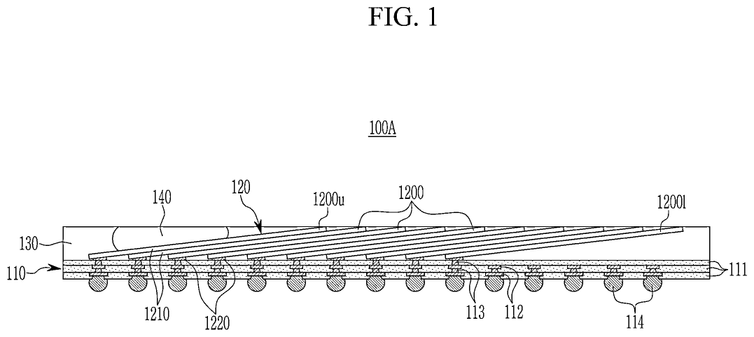

FIG. 1 is a cross-sectional view of a semiconductor package according to an example embodiment of the present disclosure.

A semiconductor package 100A may include a wiring structure 110, a chip stack structure 120 that includes a plurality of semiconductor chips 1200 and is obliquely disposed on the wiring structure 110 such that the plurality of semiconductor chips 1200 is inclined with respect to the wiring structure 110, a sealing material 130 that encapsulates the chip stack structure 120, and a support member 140 for supporting the chip stack structure 120 during the manufacturing process.

The wiring structure 110 may include insulating layers 111, wiring layers 112, and vias 113, and may further include conductive bumps 114.

The insulating layers 111 may cover the wiring layers 112 to protect them, and block or prevent an electrical short between the wiring layers 112. The insulating layers 111 may contain a photosensitive insulating material (e.g., a PID (photo imagable dielectric)) for implementing fine patterns, but is not limited thereto and may contain a polymer such as polyimide (PI) or epoxy.

The wiring layers 112 may be electrically connected to each of the plurality of semiconductor chips 1200 through the vias 113. The wiring layers 112 may be disposed on the lower surfaces of the insulating layers 111, respectively, such that each wiring layer may be covered by an insulating layer 111 disposed in another layer. Among the wiring layers 112, the lowermost wiring layer 112 may include coupling pads that are connected to the conductive bumps 114. The coupling pads may be exposed from holes in the lowermost insulating layer 111 and be connected to the conductive bumps 114.

As the formation material of the wiring layers 112, aluminum (Al), copper (Cu), gold (Au), silver (Ag), platinum (Pt), tin (Sn), chromium (Cr), palladium (Pd), lead (Pb), titanium (Ti), or an alloy thereof may be used. However, the formation material of the wiring layers is not limited thereto.

The vias 113 may pass through the insulating layers 111, and connect the wiring layers 112 disposed in different layers to each other or connect the chip stack structure 120 and the wiring layers 112 to each other. The vias 113 may include vias 113 that are in contact with connection pads 1220 of the semiconductor chips 1200. As will be described below, the wiring structure 110 may be formed after the chip stack structure 120 is encapsulated with the sealing material 130. Accordingly, the connection pads 1220 may be in contact with the vias 113, and may be connected to the wiring layers 112 through the vias 113.

The width of each via 113 may decrease in the direction from one surface toward the other surface, and for example, the width of each via 113 may decrease in the direction from the wiring layers 112 toward the connection pads 1220. When the wiring structure 110 is formed after the chip stack structure 120 is encapsulated with the sealing material 130, the width of each via 113 may decrease in the direction from the wiring layers 112 toward the connection pads 1220. However, the widths of the vias 113 are not limited thereto, and may be substantially constant along the thickness direction.

As the formation material of the vias 113, the same material as the formation material of the wiring layers 112 may be used such that the vias can be formed integrally with the wiring layers 112 without interfaces. For example, the wiring layers 112 and the vias 113 may be integrally formed by forming via holes in the insulating layers 111, forming seed layers on the bottom surfaces and wall surfaces of the via holes and the insulating layers 111, and forming plating layers on the seed layers.

The conductive bumps 114 are components for coupling the semiconductor package 100A to another structure such as a printed circuit board, etc. As the formation material of the conductive bumps 114, copper (Cu), palladium (Pd), bismuth (Bi), antimony (Sb), tin (Sn), silver (Ag), or an alloy thereof such as a tin-silver (SnAg) alloy may be used. The conductive bumps 114 may be solder balls.

The chip stack structure 120 may include the plurality of semiconductor chips 1200, and be obliquely disposed on the wiring structure 110 such that the plurality of semiconductor chips 1200 are inclined with respect to the wiring structure 110.

Each of the plurality of semiconductor chips 1200 may include a body 1210 and connection pads 1220 disposed on one surface (the lower surface in the drawing) of the body 1210.

The bodies 1210 may include a semiconductor substrate containing silicon (Si), germanium (Ge), gallium arsenide (GaAs), silicon carbide (SiC), or the like, and may include a plurality of individual elements, internal circuits, and/or interlayer insulating layers.

The connection pads 1220 are components for electrically coupling the semiconductor chips 1200 to other components such as the wiring structure 110, and may be electrically connected to the internal circuits of the bodies 1210 and the wiring structure 110. For physical and electrical coupling between the connection pads 1220 and the wiring structure 110, the plurality of semiconductor chips 1200 are stacked offset from each other such that the connection pads 1220 are exposed.

For coupling with the wiring structure 110, the connection pads 1220 may be disposed on one end portion of one surface of each of the plurality of semiconductor chips 1200. Here, one end portion of one surface of each of the plurality of semiconductor chips 1200 refers to a portion adjacent to a side surface, and includes both a portion abutting a side surface and a portion close to the side surface. The chip stack structure 120 may be obliquely disposed such that the end portions of the connection pads 1220 of the plurality of semiconductor chips 1200 having the connection pads 1220 face the wiring structure 110.

After the chip stack structure 120 is encapsulated with the sealing material 130, a grinding process for exposing the connection pads 1220 may be performed, and some portions of the connection pads 1220 may include ground surfaces by grinding the connection pads together with the sealing material 130. The ground surfaces of the connection pads 1220 may be coplanar with one surface of the sealing material 130. Further, the unground surfaces may be covered by the sealing material 130.

The sealing material 130 may encapsulate the chip stack structure 120. The sealing material 130 may be formed of a thermosetting resin such as an epoxy molding compound (EMC) or an epoxy resin, but is not limited thereto.

The support member 140 may serve to support the chip stack structure 120 during the process of manufacturing the semiconductor package 100A. The type of support member 140 is not particularly limited, and may be a paste, a spacer, or the like having an inclined surface to be able to support the chip stack structure 120 in an inclined state.

In this example embodiment, the support member 140 is disposed on the uppermost semiconductor chip 1200u of the plurality of semiconductor chips 1200, and is exposed to one surface of the sealing material 130.

As will be described below, the method of manufacturing the semiconductor package 100A may include a step of disposing the support member 140 on a support substrate 10, disposing the chip stack structure 120 on the support substrate 10 such that the chip stack structure is supported so as to be inclined by the support member 140, and encapsulating it with the sealing material 130, and the support member 140 may be in contact with the semiconductor chip 1200u to support the chip stack structure 120. For example, the support member 140 may be in contact with a surface of the semiconductor chip 1200u opposite to one surface having the connection pads 1220, to support the chip stack structure 120.

Further, the method of manufacturing the semiconductor package 100A may further include a step of removing the support substrate 10 after encapsulating, and by removing the support substrate 10, the support member 140 may be exposed to one surface of the sealing material 130. One surface of the sealing material 130 and one surface of the support member 140 that are the surfaces from which the support substrate 10 has been removed may be coplanar, and the edges of the semiconductor chips 1200 that were in contact with the support substrate 10 may be coplanar with the surfaces from which the support substrate 10 has been removed.

However, depending on design, the semiconductor package 100A may not include the support member 140. For example, when the chip stack structure 120 is disposed on a support substrate 10 having a special shape (e.g., a shape having an inclined surface to be able to support the chip stack structure 120 in a inclined state), and the chip stack structure 120 is encapsulated with the sealing material 130, the semiconductor package 100A may not include the support member 140. In this case, one surface of the chip stack structure 120 that is exposed by removing the support substrate 10, for example, the upper surface of the uppermost semiconductor chip 1200u may be exposed to the outside of the semiconductor package 100A. In some example embodiments, one surface of the chip stack structure 120 that is exposed by removing the support substrate 10 may be encapsulated with another sealing material.

According to the above example embodiment of the present disclosure, the semiconductor chips 1200 and the wiring structure 110 may be connected without using wire bonding techniques. Therefore, it is possible to provide a semiconductor package with improved power and signal characteristics. Further, the semiconductor chips 1200 may be stacked so as to be offset and be obliquely disposed such that the semiconductor chips are inclined with respect to the wiring structure 110. Therefore, it is possible to provide a semiconductor package capable of preventing an increase in package thickness and process difficulty due to the number of semiconductor chips that are stacked. Furthermore, the connection pads 1220 are directly connected to the vias 113 so as to be in contact with the vias. Therefore, it is possible to implement fine circuits, thereby capable of increasing the number of channels for increased bandwidth and increasing the degree of freedom of wiring design, and/or provide a semiconductor package with low-impedance characteristics.

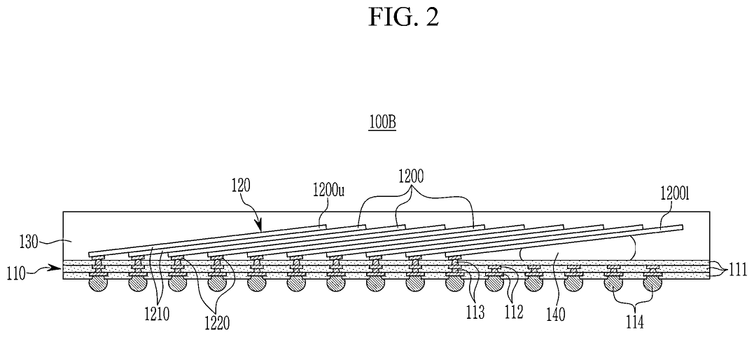

FIG. 2 is a cross-sectional view of a semiconductor package according to an example embodiment of the present disclosure.

In a semiconductor package 100B, a support member 140 may be disposed on the wiring structure 110, and be in contact with the lowermost semiconductor chip 12001 of the plurality of semiconductor chips 1200.

As will be described below, a method of manufacturing the semiconductor package 100B may include a step of disposing the support member 140 on the support substrate 10, a step of disposing the chip stack structure 120 on the support substrate 10 such that the chip stack structure is inclined by the support member 140, and a step of encapsulating the resultant structure with the sealing material 130. The support member 140 may be in contact with the semiconductor chip 12001 to support the chip stack structure 120. For example, the support member 140 may be in contact with one surface of the semiconductor chip 12001 having the connection pads 1220, to support the chip stack structure 120.

Further, the method of manufacturing the semiconductor package 100B may further include a step of removing the support substrate 10 after encapsulating and a step of forming the wiring structure 110 on the surface from which the support substrate 10 has been removed, and by removing the support substrate 10, the support member 140 may be exposed to one surface of the sealing material 130, and the wiring structure 110 may be formed on the exposed area of the support member 140. One surface of the sealing material 130 and one surface of the support member 140 that are the surfaces from which the support substrate 10 has been removed may be coplanar, and the edges of the semiconductor chips 1200 that were in contact with the support substrate 10 may be coplanar with the surfaces from which the support substrate 10 has been removed.

In the semiconductor package 100B, the edges of the connection pads 1220 formed by the lower surfaces and the side surfaces positioned in the direction toward the wiring structure 110 may be in contact with the wiring structure 110, and the vias 113 may pass through the insulating layers 111 and further pass through some portions of the sealing material 130, thereby being connected to the connection pads 1220. Further, the edges formed by the upper surfaces of the semiconductor chips 1200 and the side surfaces of one end portions of the semiconductor chips 1200 at which no connection pads 1220 is provided may be covered by the sealing material 130.

However, depending on design, the semiconductor package 100B may not include the support member 140. For example, when the chip stack structure 120 is disposed on a support substrate 10 having a special shape (e.g., a shape having an inclined surface to be able to support the chip stack structure 120 in a inclined state, and the chip stack structure 120 is encapsulated with the sealing material 130, the semiconductor package 100B may not include the support member 140. In this case, one surface of the chip stack structure 120 that is exposed by removing the support substrate 10, for example, the lower surface of the lowermost semiconductor chip 12001 may be exposed to the outside of the semiconductor package 100B. In some example embodiments, one surface of the chip stack structure 120 that is exposed by removing the support substrate 10 may be encapsulated with another sealing material.

The other components are identical to those described elsewhere in this specification, and a detailed description of those components will not be made.

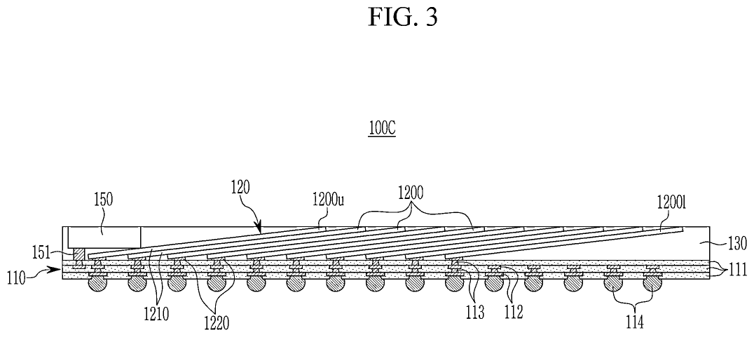

FIG. 3 is a cross-sectional view of a semiconductor package according to an example embodiment of the present disclosure.

A semiconductor package 100C may further include an electronic device 150. The electronic device 150 may serve to support the chip stack structure 120 during the process of manufacturing the semiconductor package 100C, similar to the support member 140 of the semiconductor package 100A.

The electronic device 150 may be disposed on the uppermost semiconductor chip 1200u of the plurality of semiconductor chips 1200, and be exposed to one surface of the sealing material 130. Further, the electronic device 150 may include one or more conductive pads 151, each in contact with the via 113, thereby being connected to the wiring layers 112. One surface of each conductive pads 151 may be coplanar with one surface of the sealing material 130.

The electronic device 150 may be a passive device such as a capacitor, an inductor, or the like, or may be a semiconductor chip. When the electronic device 150 is a semiconductor chip, the electronic device 150 may perform functions different from those of the semiconductor chips 1200 included in the chip stack structure 120, or may perform the same functions as those of the semiconductor chips 1200. For example, the electronic device 150 may include logic circuits, memory circuits, power lines, and so on. When the electronic device 150 is a passive device, the conductive pads 151 may be referred to as electrodes, and when the electronic device is a semiconductor chip, the conductive pads 151 may be referred to as connection pads. According to the present disclosure, the electronic device 150 may be included together with the chip stack structure 120 in the semiconductor package 100C. Therefore, it is possible to implement a semiconductor package as a system-in-package (SIP).

The other components are identical to those described elsewhere in this specification, and a detailed description of those components will not be made.

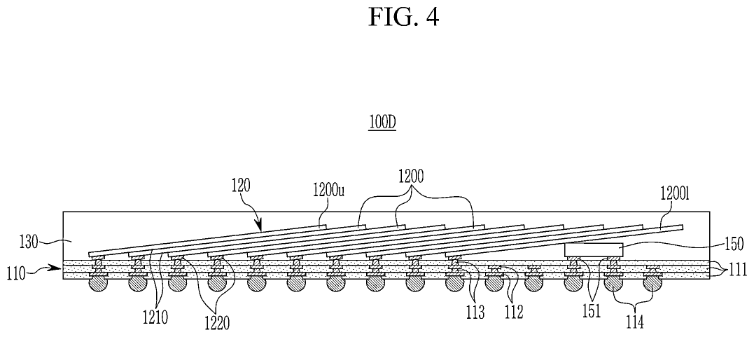

FIG. 4 is a cross-sectional view of a semiconductor package according to an example embodiment of the present disclosure.

A semiconductor package 100D may further include an electronic device 150. The electronic device 150 may serve to support the chip stack structure 120 during the process of manufacturing the semiconductor package 100D, similar to the support member 140 of the semiconductor package 100B.

The electronic device 150 may be disposed on the wiring structure 110, and be in contact with the lowermost semiconductor chip 12001 of the plurality of semiconductor chips 1200. Further, the electronic device 150 may include one or more conductive pads 151, each in contact with the via 113, thereby being connected to the wiring layers 112. One surface of each conductive pads 151 may be coplanar with the lower surface of the sealing material 130.

The other components are identical to those described elsewhere in this specification, and a detailed description of those components will not be made.

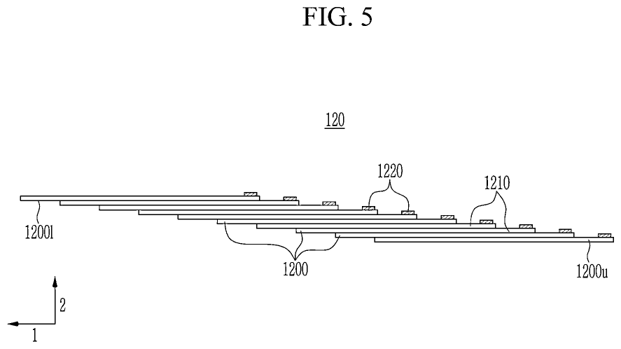

FIG. 5 is a cross-sectional view of a chip stack structure according to an example embodiment of the present disclosure.

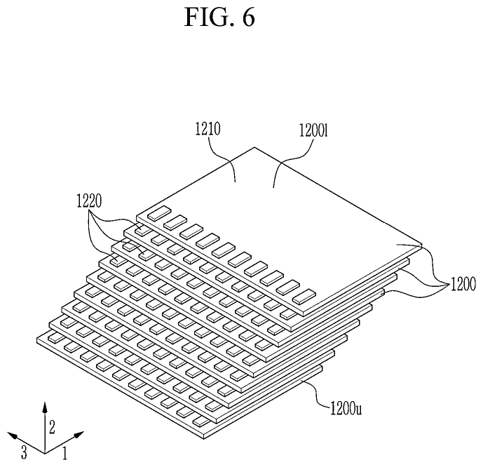

FIG. 6 is a perspective view of the chip stack structure according to the embodiment of the present disclosure.

Referring to the drawings, in the chip stack structure 120, the plurality of semiconductor chips 1200 may be stacked in a second direction 2 such that they are offset in a first direction 1 from one end portions having the connection pads 1220 toward opposite end portions. The connection pads 1220 of the plurality of stacked semiconductor chips 1200 may be sequentially positioned along the first direction 1 as seen in a plan view. The plurality of semiconductor chips 1200 may be disposed so as not to be offset in a third direction 3 perpendicular to each of the first direction 1 and the second direction 2, but may be disposed so as to be offset in the first direction 1 and the third direction 3.

The connection pads 1220 may include a plurality of connection pads 1220 disposed at intervals on one end portion of each of the plurality of semiconductor chips 1200. The plurality of connection pads 1220 may be disposed on one surface of the corresponding semiconductor chip 1200 along the third direction 3 perpendicular to each of the first direction 1 and the second direction 2.

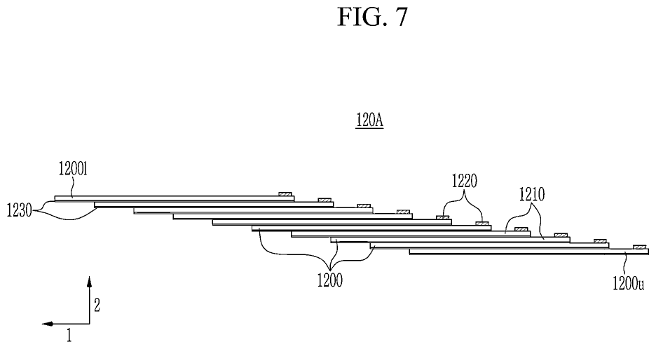

FIG. 7 is a cross-sectional view of a chip stack structure according to an example embodiment of the present disclosure.

A chip stack structure 120A may further include bonding members 1230 disposed between the plurality of semiconductor chips 1200 to bond the plurality of semiconductor chips 1200 together. The bonding members 1230 may be disposed on the other surface of each of the plurality of semiconductor chips 1200 that is opposite to one surface having the connection pads 1220 thereon.

The type of bonding members 1230 is not particularly limited, and well-known bonding members such as tape, a silicon adhesive, a polymer adhesive, die attach film (DAF) or the like may be used.

The other details are the same as those described elsewhere in this specification, and a detailed description thereof will not be made.

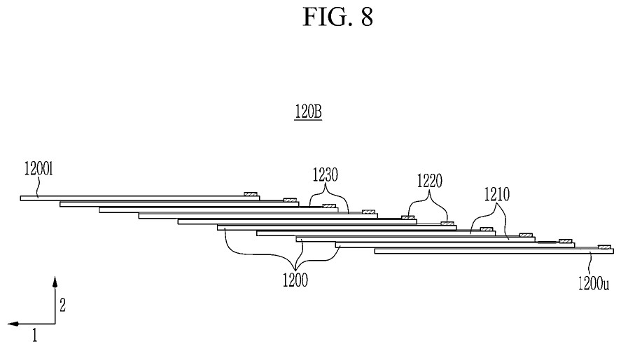

FIG. 8 is a cross-sectional view of a chip stack structure according to an example embodiment of the present disclosure.

In a chip stack structure 120B, bonding members 1230 may be disposed on one surface of each of the plurality of semiconductor chips 1200 having the connection pads 1220 thereon. The connection pads 1220 may be exposed without being covered by the bonding members 1230.

The other details are the same as those described elsewhere in this specification, and a detailed description thereof will not be made.

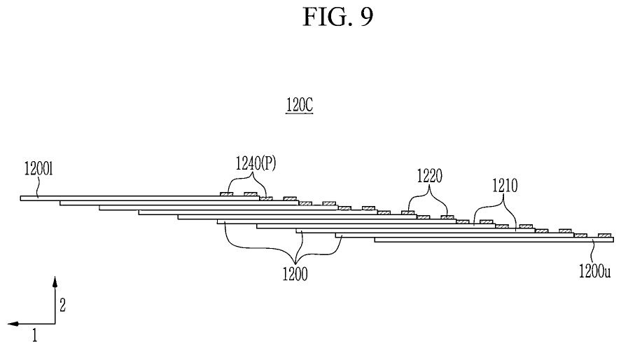

FIG. 9 is a cross-sectional view of a chip stack structure according to an example embodiment of the present disclosure.

In a chip stack structure 120C, each of the plurality of semiconductor chips 1200 may further include one or more protrusions P disposed on one surface thereof so as to be spaced apart from the connection pads 1220 in the first direction 1 in which the plurality of semiconductor chips 1200 is offset. Further, each of the plurality of semiconductor chips 1200 may be disposed on one surface of another semiconductor chip 1200 so as to be adjacent to the protrusion P of another semiconductor chip 1200. Because the plurality of semiconductor chips 1200 each include the protrusions P, it is possible to maintain the offset interval therebetween to be constant.

The protrusions P may be conductive pads 1240 containing the same material as that in the connection pads 1220. The protrusions P may be formed together with the connection pads 1220 by a plating process or the like when the connection pads 1220 are formed. As the material of the connection pads 1220 and the conductive pads 1240, for example, a metal such as copper (Cu) or aluminum (Al) may be used. The protrusions P, which are the conductive pads 1240, are not desired to be connected to the internal circuits of the plurality of semiconductor chips 1200. However, because the protrusions P do not necessarily need to be electrically connected to other components of the semiconductor package according to some example embodiments of the present disclosure, the protrusions P may be connected to the internal circuits of the plurality of semiconductor chips 1200.

The other details are the same as those described elsewhere in this specification, and a detailed description thereof will not be made.

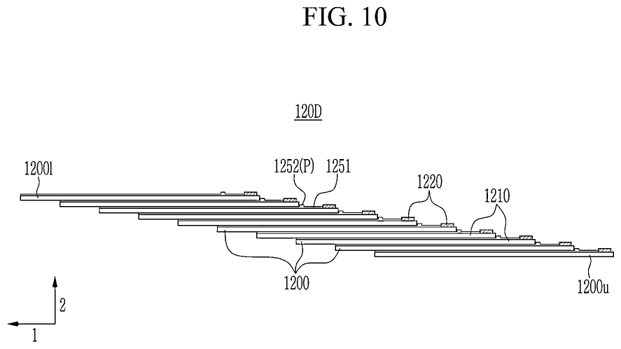

FIG. 10 is a cross-sectional view of a chip stack structure according to an example embodiment of the present disclosure.

In a chip stack structure 120D, each of the plurality of semiconductor chips 1200 may further include a passivation layer 1251 that is disposed on one surface thereof and expose the connection pads 1220. The passivation layers 1251 may serve to protect the bodies 1210 and insulate the bodies 1210 from the other components. Although not specifically shown in the drawings, each of a plurality of semiconductor chips 1200 included in chip stack structures according to other example embodiments may also further include a passivation layer 1251.

The passivation layers 1251 may be formed of an insulating material such as photosensitive polyimide (PSPI). For example, the passivation layers 1251 may be formed by applying a liquid insulating material to the bodies 1210 and patterning the passivation layers 1251 using exposure and development processes to expose the connection pads 1220.

In the chip stack structure 120D, the protrusions P may be insulating layers 1252 that are disposed on the passivation layers 1251 and contain the same material as that in the passivation layers 1251. Similar to the passivation layers, the protrusions P may be formed by applying a liquid insulating material to the passivation layers 1251 and patterning the liquid insulating material using exposure and development processes such that the protrusions have a protrusion shape. The protrusions P may have interfaces with the passivation layers 1251, but may be formed integrally with the passivation layers without interfaces, depending on the manufacturing process, the material, and the like.

The other details are the same as those described elsewhere in this specification, and a detailed description thereof will not be made.

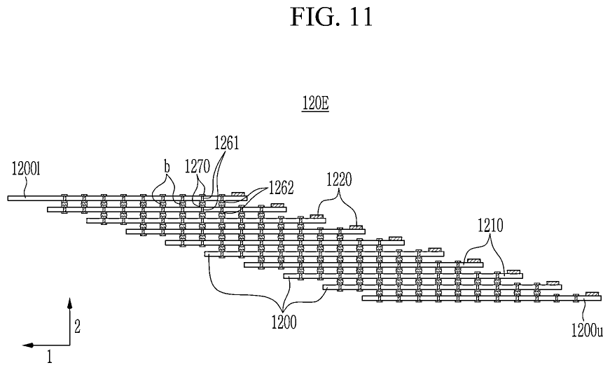

FIG. 11 is a cross-sectional view of a chip stack structure according to an example embodiment of the present disclosure.

In a chip stack structure 120E, each of the plurality of semiconductor chips 1200 may further include through-vias 1261, and the plurality of semiconductor chips 1200 may be electrically connected to one another through the through-vias 1261. Further, each of the plurality of semiconductor chips 1200 may further include conductive pads 1270 that are disposed on one surface thereof and are connected to the through-vias 1261, and via pads 1262 that are disposed on the other surface and are connected to the through-vias 1261. In the technical field to which the present disclosure belongs, the through-vias 1261 may be referred to as through-silicon electrodes, through-silicon vias (TSVs), or the like.

The conductive pads 1270 may be disposed on one surface on which the connection pads 1220 are disposed, and the via pads 1262 may be disposed on an surface opposite to the one surface on which the connection pads 1220 are disposed. The thicknesses of the conductive pads 1270 and/or the via pads 1262 may be smaller than the thickness of the connection pads 1220, and in this case, thinning of the chip stack structure 120E may be possible. However, depending on design, the thicknesses of the conductive pads 1270 and/or the via pads 1262 may be equal to the thickness of the connection pads 1220, or may be larger than the thickness of the connection pads 1220.

The chip stack structure 120E may further include conductive bumps b that are disposed between the plurality of semiconductor chips 1200 and connect the conductive pads 1270 and the via pads 1262 to each other. The conductive bumps b may be, for example, micro solder balls.

The other details are the same as those described elsewhere in this specification, and a detailed description thereof will not be made.

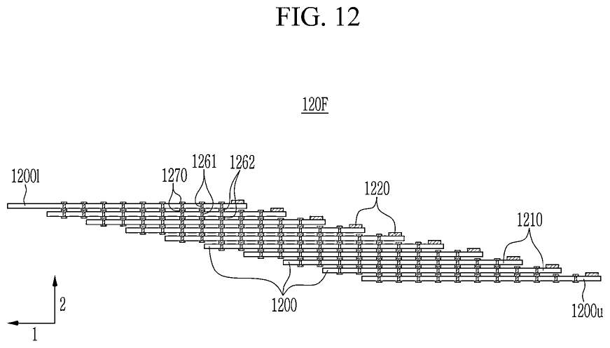

FIG. 12 is a cross-sectional view of a chip stack structure according to an example embodiment of the present disclosure.

In a chip stack structure 120F, the conductive pads 1270 of each of the plurality of semiconductor chips 1200 may be brought into contact with the via pads 1262 of another semiconductor chip 1200 adjacent thereto and be bonded to the via pads. The conductive pads 1270 and the via pads 1262 may be brought into contact with each other and be bonded by thermo-compression. In this case, on the side surfaces of the conductive pads 1270 and the via pads 1262, insulating layers may be additionally disposed, and the insulating layers on the conductive pads and the insulating layers on the via pads may be brought into contact with each other and be bonded to each other. In the technical field to which the present disclosure belongs, bonding including metal-to-metal bonding and nonmetal-to-nonmetal bonding may be referred to as hybrid bonding. In the case of applying hybrid bonding, realization of a fine pitch and thinning and reliability improvement of the semiconductor package may be possible.

The other details are the same as those described elsewhere in this specification, and a detailed description thereof will not be made.

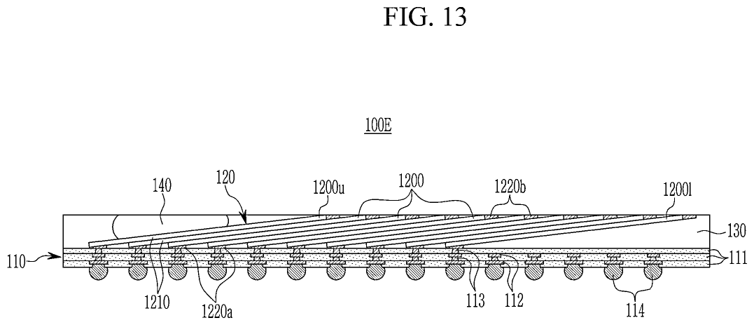

FIG. 13 is a cross-sectional view of a semiconductor package according to an example embodiment of the present disclosure.

A semiconductor package 100E is a modification of the semiconductor package 100A illustrated in FIG. 1.

In the semiconductor package 100E, each of the plurality of semiconductor chips 1200 may include first connection pads 1220a that are disposed on one end portion thereof and are electrically connected to the wiring structure 110, and second connection pads 1220b that are disposed on the other end portion thereof. The second connection pads 1220b may be exposed to one surface of the sealing material 130. The second connection pads 1220b may be exposed to one surface of the sealing material 130, for example, by grinding some portions of the sealing material 130 and the chip stack structure 120.

The second connection pads 1220b may be disposed on an end portion of one surface of each of the semiconductor chips 1200 on which the first connection pads 1220a are disposed, or may be disposed on another end portion of the one surface of each of the semiconductor chips 1200. To reduce the thickness of the chip stack structure 120, some portions of the second connection pads 1220b may be buried in the bodies 1210. However, the second connection pads 1220b are not limited thereto, and may be disposed on the bodies 1210. The thickness of the second connection pads 1220b may be smaller than the thickness of the first connection pads 1220a, or may be larger than or equal to the thickness of the first connection pads.

Meanwhile, as will be described below, on the semiconductor package 100E, another semiconductor package may be disposed, and when the second connection pads 1220b are exposed to one surface of the sealing material 130, the second connection pads 1220b may be electrically connected to another semiconductor package.

The other components are identical to those described elsewhere in this specification, and a detailed description of those components will not be made.

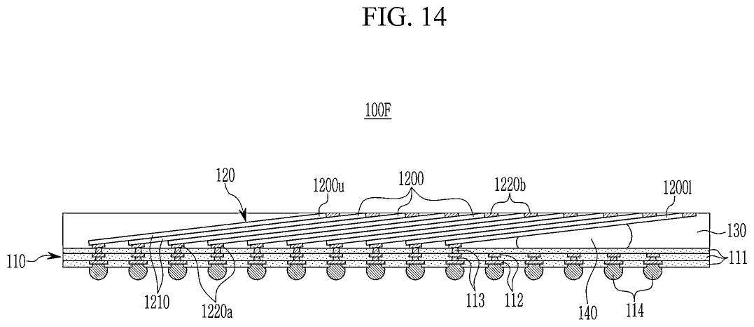

FIG. 14 is a cross-sectional view of a semiconductor package according to an example embodiment of the present disclosure.

A semiconductor package 100F is a modification of the semiconductor package 100B illustrated in FIG. 2.

In the semiconductor package 100F, each of the plurality of semiconductor chips 1200 may include first connection pads 1220a that are disposed on one end portion and are electrically connected to the wiring structure 110, and second connection pads 1220b that are disposed on the other end portion. The second connection pads 1220b may be exposed to one surface of the sealing material 130. The second connection pads 1220b may be exposed to one surface of the sealing material 130, for example, by grinding some portions of the sealing material 130 and the chip stack structure 120.

The second connection pads 1220b may be disposed on an end portion of one surface of each of the semiconductor chips 1200 on which the first connection pads 1220a are disposed, or may be disposed on another end portion of the one surface of each of the semiconductor chips 1200. To reduce the thickness of the chip stack structure 120, some portions of the second connection pads 1220b may be buried in the bodies 1210. However, the second connection pads 1220b are not limited thereto, and may be disposed on the bodies 1210. The thickness of the second connection pads 1220b may be smaller than the thickness of the first connection pads 1220a, or may be larger than or equal to the thickness of the first connection pads.

Meanwhile, as will be described below, on the semiconductor package 100F, another semiconductor package may be disposed, and when the second connection pads 1220b are exposed to one surface of the sealing material 130, the second connection pads 1220b may be electrically connected to another semiconductor package.

The other components are identical to those described elsewhere in this specification, and a detailed description of those components will not be made.

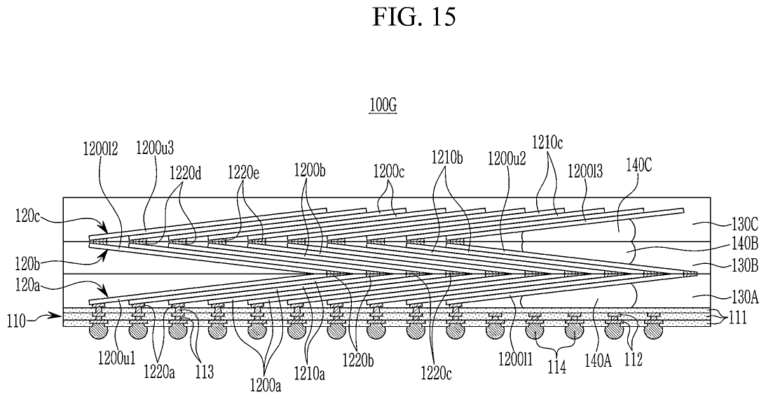

FIG. 15 is a cross-sectional view of a semiconductor package according to an example embodiment of the present disclosure.

A semiconductor package 100G may include a first chip stack structure 120a that includes a wiring structure 110 and a plurality of first semiconductor chips 1200a, a first sealing material 130A, a second chip stack structure 120b that includes a plurality of second semiconductor chips 1200b, a second sealing material 130B, a third chip stack structure 120c that includes a plurality of third semiconductor chips 1200c, and a third sealing material 130C. The first chip stack structure 120a, the second chip stack structure 120b, and the third chip stack structure 120c may be disposed so as to be inclined in alternating directions, forming a zigzag shape.

The number of chip stack structures 120 is not particularly limited, and for example, the semiconductor package 100G may include only the first chip stack structure 120a and the second chip stack structure 120b, and may not include the third chip stack structure 120c. In some example embodiments, the semiconductor package 100G may further include at least one chip stack structure disposed on the third chip stack structure 120c.

The first chip stack structure 120a includes the plurality of first semiconductor chips 1200a stacked so as to be offset, and may be disposed on the wiring structure 110 obliquely along one direction of the alternating directions such that the plurality of first semiconductor chips 1200a is inclined with respect to the wiring structure 110.

Each of the plurality of first semiconductor chips 1200a may include first connection pads 1220a that are disposed on one end portion and are electrically connected to the wiring structure 110, and second connection pads 1220b that are disposed on the other end portion. The second connection pads 1220b may be exposed to one surface of the first sealing material 130A for coupling with third connection pads 1220c.

The second chip stack structure 120b may include the plurality of second semiconductor chips 1200b stacked so as to be offset, and may be disposed on the first chip stack structure 120a obliquely along the direction alternating with the direction in which the first chip stack structure 120a is inclined.

Each of the plurality of second semiconductor chips 1200b may include the third connection pads 1220c that are displayed on one end portion and are electrically connected to the second connection pads 1220b. The second connection pads 1220b and the third connection pads 1220c are brought into contact with each other and are bonded. If desired, between the second connection pads 1220b and the third connection pads 1220c, conductive bumps (not shown in the drawing) may be additionally disposed, and the second connection pads 1220b and the third connection pads 1220c may be connected to each other through the conductive bumps (not shown in the drawing). Further, when the semiconductor package 100G further includes the third chip stack structure 120c, each of the plurality of second semiconductor chips 1200b may further include fourth connection pads 1220d that are disposed on the other end portion. The fourth connection pads 1220d may be exposed to one surface of the second sealing material 130B for coupling with fifth connection pads 1220e.

The third chip stack structure 120c may include the plurality of third semiconductor chips 1200c stacked so as to be offset, and may be disposed on the second chip stack structure 120b obliquely in the direction alternating with the direction in which the second chip stack structure 120b is inclined.

Each of the plurality of third semiconductor chips 1200c may include the fifth connection pads 1220e that are disposed on one end portion and are electrically connected to the fourth connection pads 1220d. The fourth connection pads 1220d and the fifth connection pads 1220e are brought into contact with each other and bonded. If desired, between the fourth connection pads 1220d and the fifth connection pads 1220e, conductive bumps (not shown in the drawing) may be additionally disposed, and the fourth connection pads 1220d and the fifth connection pads 1220e may be connected to each other through the conductive bumps (not shown in the drawing).

The first sealing material 130A, the second sealing material 130B, and the third sealing material 130C may encapsulate the first chip stack structure 120a, the second chip stack structure 120b, and the third chip stack structure 120c, respectively. The first sealing material 130A, the second sealing material 130B, and the third sealing material 130C may have interfaces with one another, but may be formed integrally with one another without interfaces, depending on the manufacturing processes, the materials, and the like. In some example embodiments, the semiconductor package 100G may further include an additional sealing material that encapsulates the first sealing material 130A, the second sealing material 130B, and the third sealing material 130C.

The semiconductor package 100G may include at least one support member 140. For example, the semiconductor package 100G may include at least one of a first support member 140A for supporting the first chip stack structure 120a, a second support member 140B for supporting the second chip stack structure 120b, or a third support member 140C for supporting the third chip stack structure 120c during the manufacturing process.

The first support member 140A may be disposed on the wiring structure 110 and be in contact with the lowermost first semiconductor chip 120011 of the plurality of first semiconductor chips 1200a. In some example embodiments, the first support member 140A may be disposed on the uppermost first semiconductor chip 1200u1 of the plurality of first semiconductor chips 1200a and be exposed to one surface of the first sealing material 130A.

The second support member 140B may be disposed on the uppermost second semiconductor chip 1200u2 of the plurality of semiconductor chips 1200b and be exposed to one surface of the second sealing material 130B. In some example embodiments, the second support member 140B may be disposed on the first sealing material 130A and be in contact with the lowermost second semiconductor chip 120012 of the plurality of second semiconductor chips 1200b.

The third support member 140C may be disposed on the second sealing material 130B and be in contact with the lowermost third semiconductor chip 120013 of the plurality of third semiconductor chips 1200c. In some example embodiments, the third support member 140C may be disposed on the uppermost third semiconductor chip 1200u3 of the plurality of third semiconductor chips 1200c and be exposed to one surface of the third sealing material 130C.

The other components are identical to those described elsewhere in this specification, and a detailed description of those components will not be made.

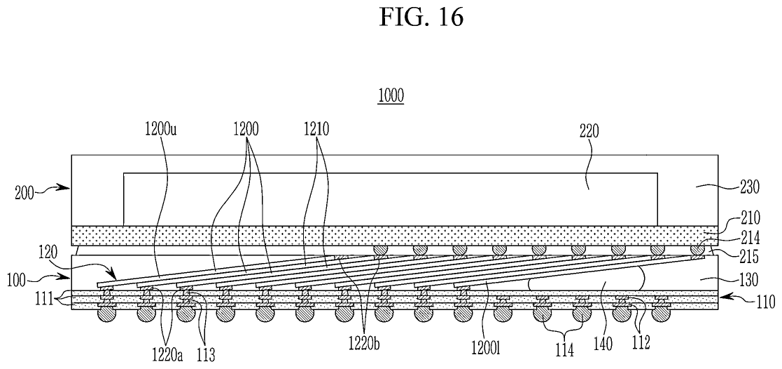

FIG. 16 is a cross-sectional view of a semiconductor package according to an example embodiment of the present disclosure.

A semiconductor package 1000 may include a first semiconductor package 100 and a second semiconductor package 200 that is disposed on the first semiconductor package 100.

The first semiconductor package 100 may be one of the above-described semiconductor packages according to the present disclosure, and may be a semiconductor package having the structure shown in FIG. 13 or FIG. 14 for coupling with the second semiconductor package 200. Accordingly, each of the plurality of semiconductor chips 1200 may include first connection pads 1220a that are disposed on one end portion and are electrically connected to the wiring structure 110, and second connection pads 1220b that are disposed on the other end portion. The second connection pads 1220b may be electrically connected to the second semiconductor package 200 and be exposed to one surface of the sealing material 130.

The second semiconductor package 200 may include a second semiconductor chip 220. Further, the second semiconductor package 200 may further include a wiring structure 210 on which the second semiconductor chip 220 is disposed, and a sealing material 230 that encapsulates the second semiconductor chip 220.

The wiring structure 210 may be a printed circuit board, a redistribution structure, or the like that is commonly used in the semiconductor package field. The wiring structure 210 may include insulating layers, wiring layers, and vias, and may further include conductive bumps 214 for coupling with the first semiconductor package 100, and an underfill 215 that surround the conductive bumps 214. The conductive bumps 214 may be disposed on the second connection pads 1220b exposed to one surface of the sealing material 130 to connect the first semiconductor package 100 and the second semiconductor package 200 with each other.

The second semiconductor chip 220 may be electrically connected to each of the first semiconductor chips 1200 of the chip stack structure 120. The type of second semiconductor chip 220 is not particularly limited, and may be a logic chip, a memory chip, or the like.

The sealing material 230 may be formed of a thermosetting resin such as an epoxy molding compound (EMC) or an epoxy resin, similar to the sealing material 130, but is not limited thereto.

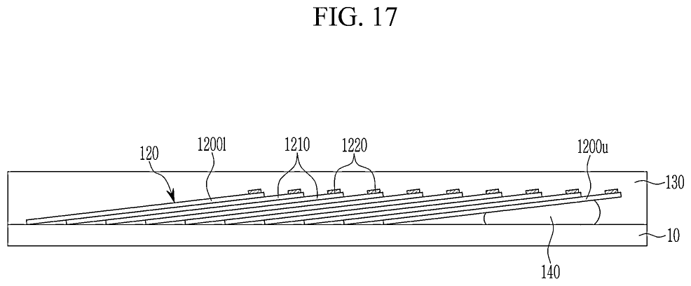

FIGS. 17 to 19 illustrate a process of manufacturing the semiconductor package shown in FIG. 1, according to an example embodiment.

Referring to FIG. 17, first, the support member 140 may be disposed on the support substrate 10, and the chip stack structure 120 may be disposed on the support substrate 10 such that the chip stack structure is supported so as to be inclined by the support member 140, and the support member 140 and the chip stack structure 120 may be encapsulated with the sealing material 130.

The support member 140 may have an inclined surface, and the chip stack structure 120 may be supported on the inclined surface so as to be inclined. The support member 140 may be in contact with the semiconductor chip 1200u, thereby being capable of supporting the chip stack structure 120. For example, the support member 140 may be in contact with a surface of the semiconductor chip 1200u that is opposite to one surface having the connection pads 1220, to support the chip stack structure 120. In some example embodiment, the chip stack structure 120 may be disposed on a support substrate 10 having a special shape with an inclined surface, without using the support member 140, and be encapsulated with the sealing material 130.

The chip stack structure 120 may be disposed on the support member 140 such that a surface of each of the plurality of semiconductor chips 1200 that is opposite to a surface having the connection pads 1220 faces the support substrate 10. Further, one end portion of the chip stack structure 120 having no connection pads 1220 thereon may be obliquely disposed so as to face the support substrate 10 such that the one end portion of each of the plurality of semiconductor chips 1200 is in contact with the support substrate 10.

The step of encapsulating the chip stack structure 120 and the support member 140 with the sealing material 130 may be performed through a well-known method such as compression molding, transfer molding, or the like.

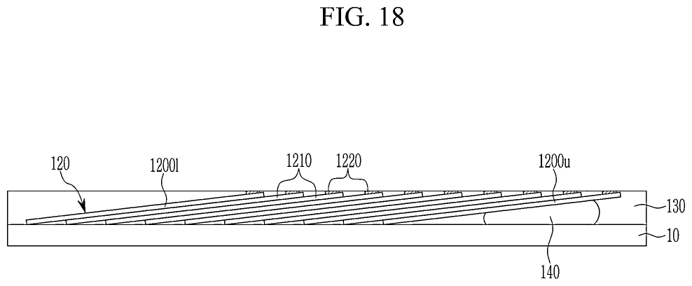

Next, referring to FIG. 18, the sealing material 130 may be ground so as to expose the connection pads 1220 on the plurality of semiconductor chips 1200. Some portions of the connection pads 1220 may include ground surfaces by grinding the connection pads together with the sealing material 130. The ground surfaces of the connection pads 1220 may be coplanar with the ground surface of the sealing material 130.

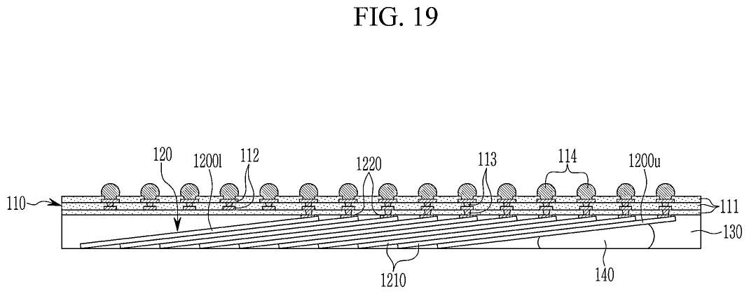

Next, referring to FIG. 19, on the sealing material 130, the wiring structure 110 may be formed so as to be electrically connected to the connection pads 1220 of each of the plurality of semiconductor chips 1200, and the support substrate 10 may be removed. By removing the support substrate 10, the support member 140 may be exposed to one surface of the sealing material 130. One surface of the sealing material 130 and one surface of the support member 140 that are the surfaces from which the support substrate 10 has been removed may be coplanar, and the edges of the semiconductor chips 1200 that were in contact with the support substrate 10 may be coplanar with the surfaces from which the support substrate 10 has been removed.

The wiring structure 110 may be formed by repeatedly and sequentially forming the insulating layers 111, the vias 113, and the wiring layers 112. For example, the wiring structure 110 may include a step of forming the vias 113 such that the vias pass through the insulating layers 111 and are in contact with the connection pads 1220. Accordingly, it is possible to implement fine circuits, thereby being capable of increasing the number of channels for increased bandwidth and increasing the degree of freedom of wiring design, and provide a semiconductor package with low-impedance characteristics.

The other details are the same as those described elsewhere in this specification, and a detailed description thereof will not be made.

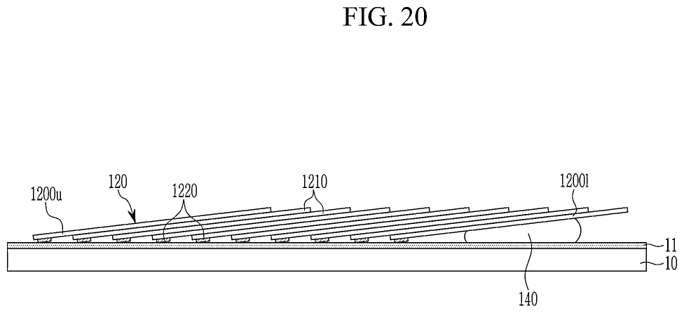

FIGS. 20 to 22 illustrate a process of manufacturing the semiconductor package shown in FIG. 2, according to an example embodiment.

Referring to FIG. 20, first, the support member 140 may be disposed on a support substrate 10 including an adhesive film 11, and the chip stack structure 120 including the plurality of semiconductor chips 1200 may be disposed on the support member 140.

The adhesive film 11 may be, for example, a die attach film (DAF) that is commonly used in the semiconductor industry, but is not limited thereto.

The support member 140 may have an inclined surface, and the chip stack structure 120 may be supported on the inclined surface so as to be inclined. The support member 140 may be in contact with the semiconductor chip 12001 to support the chip stack structure 120. For example, the support member 140 may be in contact with one surface of the semiconductor chip 12001 having the connection pads 1220 thereon, to support the chip stack structure 120. In some example embodiments, the chip stack structure 120 may be disposed on a support substrate 10 having a special shape with an inclined surface, without using the support member 140, and be encapsulated with the sealing material 130.

The chip stack structure 120 may be disposed on the support member 140 such that the surface of each of the plurality of semiconductor chips 1200 having the connection pads 1220 thereon faces the support substrate 10. Further, one end portion having the connection pads 1220 may be obliquely disposed so as to face the support substrate 10 such that the one end portion of each of the plurality of semiconductor chips 1200 is in contact with the support substrate 10.

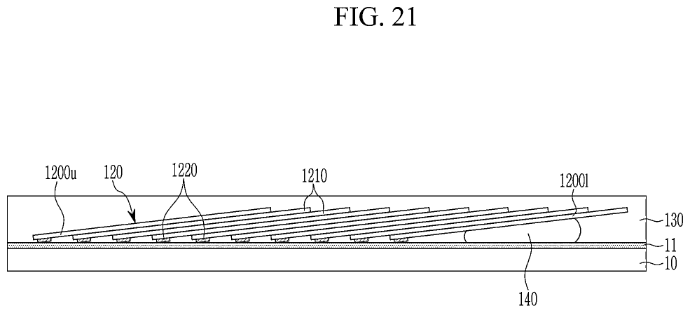

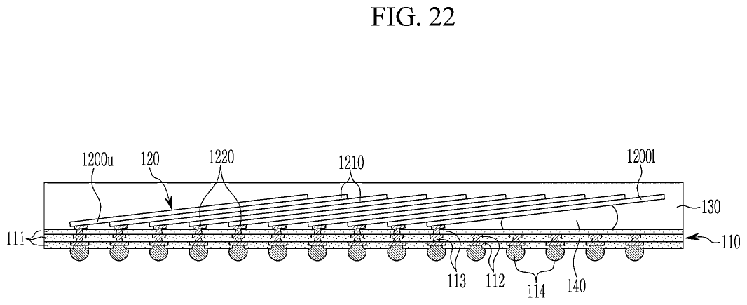

Next, referring to FIGS. 21 and 22, the support member 140 and the chip stack structure 120 may be encapsulated with the sealing material 130, and the support substrate 10 including the adhesive film 11 may be removed, and the wiring structure 110 may be formed on the sealing material 130 so as to be electrically connected to the connection pads 1220 of each of the plurality of semiconductor chips 1200.

The step of encapsulating the chip stack structure 120 and the support member 140 with the sealing material 130 may be performed through a well-known method such as compression molding, transfer molding, or the like.

The adhesive film 11 may be separated from the sealing material 130 by applying heat to the support substrate 10, and thus the support substrate may be removed. However, example embodiments of the present disclosure are not limited thereto. By removing the support substrate 10, the support member 140 may be exposed to one surface of the sealing material 130, and the wiring structure 110 may be formed on the exposed area of the support member 140. One surface of the sealing material 130 and one surface of the support member 140 that are the surfaces from which the support substrate 10 has been removed may be coplanar, and the edges of the semiconductor chips 1200 that were in contact with the support substrate 10 may be coplanar with the surfaces from which the support substrate 10 has been removed.

The other details are the same as those described elsewhere in this specification, and a detailed description thereof will not be made.

The individual example embodiments may be implemented in combination with one another. Accordingly, the contents described in one example embodiment of the present disclosure may be equally applied to other example embodiments of the present disclosure unless contradicted.

While this disclosure has been described in connection with what is presently considered to be some example embodiments, it is to be understood that the disclosure is not limited to the disclosed example embodiments. On the contrary, it is intended to cover various modifications and equivalent arrangements included within the spirit and scope of the appended claims.

What is claimed is:

1. A semiconductor package comprising:
a wiring structure including insulating layers, wiring layers, and vias;
a chip stack structure including a plurality of semiconductor chips, the chip stack structure being oblique on the wiring structure such that the plurality of semiconductor chips is inclined with respect to the wiring structure; and
a sealing material encapsulating the chip stack structure,
wherein each of the plurality of semiconductor chips includes connection pads on one surface thereof, the plurality of semiconductor chips being offset with each other such that the connection pads are exposed, and
each of the connection pads of each of the plurality of semiconductor chips is in contact with a corresponding one of the vias and connected to the wiring layers.

2. The semiconductor package of claim 1, further comprising:
a support member on an uppermost semiconductor chip of the plurality of semiconductor chips and exposed to one surface of the sealing material.

3. The semiconductor package of claim 1, further comprising:
a support member on the wiring structure and in contact with a lowermost semiconductor chip of the plurality of semiconductor chips.

4. The semiconductor package of claim 1, further comprising:
an electronic device on an uppermost semiconductor chip of the plurality of semiconductor chips and exposed to one surface of the sealing material,
where the electronic device includes one or more conductive pads, each of the one or more conductive pads being in contact with a corresponding one of the vias and connected to the wiring layers.

5. The semiconductor package of claim 1, further comprising:
an electronic device on the wiring structure and in contact with a lowermost semiconductor chip of the plurality of semiconductor chips,
where the electronic device includes one or more conductive pads, each of the one or more conductive pads being in contact with a corresponding one of the vias and connected to the wiring layers.

6. The semiconductor package of claim 1, wherein
the chip stack structure further includes bonding members between the plurality of semiconductor chips.

7. The semiconductor package of claim 1, wherein
each of the plurality of semiconductor chips further includes a protrusion on the one surface thereof, the protrusion being spaced apart from a corresponding one of the connection pads in a direction in which the plurality of semiconductor chips are offset with each other, and
each of the plurality of semiconductor chips is on the one surface of another semiconductor chip of the plurality of semiconductor chips, to be adjacent to the protrusion of the another semiconductor chip.

8. The semiconductor package of claim 7, wherein
the protrusion is a conductive pad and includes a same material as that the connection pad.

9. The semiconductor package of claim 7, wherein
each of the plurality of semiconductor chips further includes a passivation layer on the one surface thereof and exposes the connection pad, and
the protrusion is an insulating layer on the passivation layer and includes a same material as the passivation layer.

10. The semiconductor package of claim 1, wherein
each of the plurality of semiconductor chips further includes through-vias, and
the plurality of semiconductor chips are electrically connected to one another through the through-vias.

11. The semiconductor package of claim 10, wherein
each of the plurality of semiconductor chips further includes,
conductive pads on the one surface thereof and connected to the through-vias, and
via pads on another surface thereof and connected to the through-vias, the another surface being opposite to the one surface, and
the chip stack structure further includes conductive bumps between the plurality of semiconductor chips and connecting the conductive pads and the via pads.

12. The semiconductor package of claim 10, wherein
each of the plurality of semiconductor chips further includes,
conductive pads on the one surface thereof and connected to the through-vias, and
via pads on another surface thereof and connected to the through-vias, and
the conductive pads of each of the plurality of semiconductor chips are in contact with the via pads of another semiconductor chip adjacent thereto, from among the plurality of semiconductor chips.

13. The semiconductor package of claim 1, wherein
a width of each of the vias decreases in a direction from the wiring layers toward the connection pads.

14. The semiconductor package of claim 1, wherein
the connection pads include a plurality of connection pads, the plurality of connection pads being at intervals on one end portion of each of the plurality of semiconductor chips, and
the plurality of semiconductor chips are offset with each other in a direction from the one end portion toward another end portion, the one end portion and the another end portion being opposite end portions of each of the plurality of semiconductor chips.

15. A semiconductor package comprising:
a wiring structure;
a first chip stack structure on the wiring structure and including a plurality of first semiconductor chips, the plurality of first semiconductor chips being offset with each other, the first chip stack structure being oblique along a first direction such that the plurality of first semiconductor chips are inclined with respect to the wiring structure;
a first sealing material encapsulating the first chip stack structure;
a second chip stack structure on the first chip stack structure and including a plurality of second semiconductor chips being offset with each other, and the second chip stack structure being oblique along a second direction forming an angle with the first direction; and
a second sealing material encapsulating the second chip stack structure,
wherein each of the plurality of first semiconductor chips includes,
first connection pads on one end portion thereof and electrically connected to the wiring structure, and
second connection pads on another end portion thereof, the one end portion and the another end portion of each of the plurality of first semiconductor chips being opposite to each other, and
each of the plurality of second semiconductor chips includes third connection pads on one end portion thereof and electrically connected to the second connection pad.

16. The semiconductor package of claim 15, wherein
the second connection pads and the third connection pads are in contact with each other.

17. The semiconductor package of claim 15, further comprising:
a third chip stack structure including a plurality of third semiconductor chips being offset with each other, the third chip stack structure being on the second chip stack structure and being oblique along the first direction; and
a third sealing material encapsulating the third chip stack structure,
wherein each of the plurality of second semiconductor chips further includes fourth connection pads on another end portion thereof, the one end portion and the another end portion of each of the plurality of second semiconductor chips being opposite to each other, and
each of the plurality of third semiconductor chips includes fifth connection pads being on one end portion thereof and electrically connected to the fourth connection pad.

18. The semiconductor package of claim 17, further comprising:
at least one of
a first support member on the wiring structure and being in contact with a lowermost first semiconductor chip of the plurality of first semiconductor chips,
a second support member on an uppermost second semiconductor chip of the plurality of second semiconductor chips and exposed to one surface of the second sealing material, or
a third support member on the second sealing material and in contact with a lowermost third semiconductor chip of the plurality of third semiconductor chips.

19. A semiconductor package comprising:
a first semiconductor package; and
a second semiconductor package on the first semiconductor package,
wherein the first semiconductor package includes,
a wiring structure,
a chip stack structure including a plurality of first semiconductor chips being offset with each other, the chip stack structure being oblique on the wiring structure such that the plurality of first semiconductor chips are inclined with respect to the wiring structure, and
a sealing material encapsulating the chip stack structure,
each of the plurality of first semiconductor chips includes,
first connection pads being on one end portion thereof and electrically connected to the wiring structure, and
second connection pads being on another end portion of first semiconductor chip and electrically connected to the second semiconductor package, and
the second semiconductor package includes a plurality of second semiconductor chips.

20. The semiconductor package of claim 19, wherein
the second connection pads are exposed to one surface of the sealing material.
